(19) United States
(12) Patent Application Publication
(10) Pub. No.: US 2018/0168032 A1
(43) Pub. Date: Jun. 14, 2018

(54) A Method for Making Patterned Conductive Textiles

(71) Applicant: DST Innovations Limited, Bridgend (GB)

(72) Inventors: Anthony Miles, Cwmaman, Aberdare (GB); Benjamin John Masheder, Portishead Bristol (GB)

(73) Assignee: DST Innovations Limited, Bridgend (GB)

(21) Appl. No.: 15/580,824

(22) PCT Filed: Jun. 17, 2016
(86) PCT No.: PCT/GB2016/051832

§ 371 Date: Dec. 8, 2017

(30) Foreign Application Priority Data
Jun. 19, 2015 (GB) 1510863.2

(51) Int. Cl. H05K 1/02; H05K 1/03; H05K 3/06; C23F 1/30; D06M 10/02; D06M 11/74; D06M 11/83; D06M 23/16

(52) U.S. Cl. CPC H05K 1/0283; H05K 1/038; H05K 3/067; H05K 3/061; C23F 1/30; D06M 10/025; D10B 2501/00; D06M 11/83; D06M 23/16; H05K 2203/1572; H05K 2201/0323; H05K 2203/1545; H05K 2203/1461; D06M 11/74

(57) ABSTRACT

A method of forming a conductive/nonconductive pattern on a conductive particle-coated fabric uses chemical etching techniques to remove specific areas of conductive material from the fabric, producing non-conductive areas where the fabric was exposed to an etching agent, and leaving conductive areas where the conductive coating was protected by an etch-resistant coating.

### FIELD OF THE INVENTION

The present invention relates to textile fabrics that carry an electrically conductive coating.

### BACKGROUND OF THE INVENTION

The following discussion is not to be taken as an admission of relevant prior art.

Conductive textiles are characterised by a fabric woven with either solid metal wires or nonconductive fibres that are coated with a conductive material such as a conductive polymer, metal particles or conductive inorganic particles. Such fabrics typically have a conductivity of <1000 Ohms per square and are thought to have application in resistant heating, transparent conductors and wearable electronics. Conductive textiles of this type typically possess comparable conductivity in all directions, although textiles with a tailored conductivity gradient have been prepared by combining the use of conductive and non-conductive fibres, as disclosed in U.S. Pat. No. 5,102,727, or incompletely etching the fabric with a chemically reducing agent to systematically reduce its conductivity, as disclosed in U.S. Pat. No. 5,162,135. However, with the rise of wearable electronic devices the ability to produce complex conductive patterns on mass produced uniformly conductive fabrics is increasingly desirable.

A number of methods exist that allow the production of patterned conductive fabrics but none are suitable for the production of circuit designs, especially complex circuits suitable for the attachment of typical surface mount devices (SMDs) with small form factors. This requires small feature sizes and small inter-feature pitches, typically 0.2 mm, or even 0.1 mm.

The ability to form transparent conductive patterns on a fabric material would allow conventional electrical circuitry to be combined with a variety of fabrics in the formation of an electronic device that acts, moves and feels similar to other textile fabrics. This would allow the formation of wearable electronic devices that are more desirable than those constructed using typical electronic connectors and components that do not have the ability to move and act like textile fabrics because they are hindered by inflexible and rigid components. The ability to easily form complex conductive tracks and circuits from previously uniformly conductive fabric would allow greater uptake of this technology.

Prior art conductive fabrics often contain conductive metal wires, metal foils or metal coated nonconductive fibres incorporated onto or into conventional fabrics using adhesives or by stitching the conductive fibre into the conventional fabric [Patent No's. US 2007014901, WO 2006113918, and KR 1020140045223]. These methods allow for the formation of conductive patterns in and on the fabric, useful for many applications such as wearable sensors, flexible circuit tracks, solderable connections, simple aerials and many other uses not included here. However, these approaches are not ideal because adding metal wires or adhesive layers will significantly increase the weight and rigidity of the fabrics, similarly stitching additional fibres into the fabrics will cause the fabric to act in a manner significantly different from the original fabric. Changing the characteristics of the fabrics, such as flow, feel and how the fabric hangs, is seen as very disadvantageous to many conductive fabric applications, where a seamless, fully cohesive design is important. Previously disclosed methods overcame the problems of stitching or gluing conductive fibres to a conventional fabric by coating a nonconductive piece of fabric with a conductive coating making the fibres conductive. This can be done by, but is not limited to, coating the fibres of the fabric with conductive metals such as silver or combinations of conductive metals or alloys of conductive metals as well as conductive polymers such as polyaniline. Approaches similar to and including these examples are well known and have demonstrated that they are suitable methods of creating large areas and block of conductive fabric.

It should be noted that conductive fabric formed from solid metal wires or non-conductive fibres coated with a conductive layer with comparable conductivity may exhibit a directionally biased conductivity due to the construction of the fabric, even though the fibres which make up the fabric were uniformly coated. For example, the directional construction bias may occur if there is substantially more fibre mass in the warp direction (the direction of the threads that run the length of a material and perpendicular to the fill threads) than in the fill direction (the direction of the threads that run the width of a material and perpendicular to the warp threads), resulting in more conductivity in the warp direction than the fill direction.

A similar associated technique known in the prior art describes how it is possible to coat specific areas of a non-conductive fabric with a conductive coating pattern to form a conductive pattern on a fabric [Patent No. US 20090266788]. For example, such a process can be done using screen printing to deposit a conductive material, typically a conductive polymer onto the non-conductive fabric in the required pattern. However, like many printing technique, screen printing can only deposit the conductive material on one side of the fabric at once. The result is that roughly half of the fibre surface is uncoated and therefore non-conductive. Unfavourably this reduces the conductivity of the resultant fabric and would provide significantly lower conductivity, making it unsuitable for many applications. For instance, it would also not provide an adequate area of conductive circuit to adequately attach a significant number of SMDs whilst also limiting the application of any components to only one side of the fabric. As a subsequent step it is possible to apply a second conductive coating to the other side of the fabric with a mirror image design but the tolerance for alignment of the second print to the first is very small for complex small designs and would be very difficult to do in a roll-to-roll production process. Adding in a second printing step for printing the second side of the non-conductive fabric with a conductive coating will also add in a significant error for misalignment and is therefore unsuitable for production of complex conductive circuits on fabric.

A significant disadvantage of coating a nonconductive fabric with a conductive coating after it has been formed into a fabric is that it does not allow the conductive material to coat the area of the fibres which are between the fibres, where the weft and warp fibres come into contact with each other. The place where the warp and weft fibres touch will not be coated using this technique because they are in constant contact with each other and therefore no conductive material will be present in these areas. Whilst there will be some conductive material around the edges of these joints the coating will be absent where the fibres are in contact. It has been found that this makes the electrical connection poor, prone to breaking or damage, and gives the fabric or fabric pattern an inconsistent resistivity, especially under flexing or stretching. This presents a significant problem because not having a coating on the joints between the warp and weft fibres will reduce the conductivity of the fabric and prevent a reliable circuit connection being formed between the fibres. This will be unfavourable for many applications, specifically for complex circuits with many different circuit track directions which will need good x- and y-axis conductivity in the same circuit track. This is also important for forming complex fabric circuits, especially when SMDs are incorporated because a stable conductive path is necessary for many components to operate, especially when the fabric is being flexed, for instance when it is being worn. A lack of conductive material between joints will have much more significance when a high thread count (threads per inch) fabric is required because there will be a decidedly more joints between the fibres present and therefore more of the fibres will be covered and hidden during the application of a conductive coating. This will make the resultant material less conductive, because there will be less of the fibres covered as well as more joints between the fibres and therefore more poor connections between the warp and weft fibres.

The patterning of conductive textiles that have a conductive organic polymer deposited onto non-conductive fibres is disclosed in U.S. Pat. No. 5,624,736 and U.S. Pat. No. 5,292,573, wherein chemical etchants are used to selectively remove patterns of conductive polymers. Despite their inherently good flexibility and transparency it has been found that conductive polymers are not ideal for applications in conductive circuits on fabric. This is in part a result of the relatively low conductivity of these organic polymers (PEDOT:PSS <4600 S/m) compared to conductive inorganic materials such as silver (6×10⁷ S/m) or carbon (1×10⁸ S/m). The organic nature of the conductive polymers, containing a mostly C—C backbone, means that they are highly susceptible to thermal damage something which has been found to be a problem when they are used to create high current carrying circuits or at the contacts between the polymers and materials such as tin-coated SMD electrodes, where the polymer will often burn out and stop working. Conductive polymers have also been found to be easily damaged by physical abrasion or by exposure to sunlight, making their use in conductive fabric circuits problematic and flawed, especially for use in wearable or outdoor devices.

Removal of conductive particles from solid substrates is typically performed using an aggressive chemical etching agent which either greatly reduces the conductivity of the conductive material or altogether removes the conductive material into solution. This can involve the use of inorganic salts, acids, bases, and oxidizing or reducing agents and is typically performed by submerging the material to be etched into an etching solution and leaving it there until the desired amount of etching has been achieved. Solution etching is typically used because the free-motion within a solution allows any etched material to dissipate from the surface, allowing the etchant a greater ability to act upon more material and therefore more efficiently perform its task. An alternative to solution etching is etching paste, which is a paste that when deposited onto a surface has the ability to remove unwanted material in situ. The etching paste is then typically washed off the surface with water to leave the etched pattern behind. The use of etching paste has the advantage of fewer processing steps than using etching solution because it requires fewer washing steps and no immersion. An example of the use of etching paste is described in Chinese Patent number 103215592 “Etching cream, applications of etching cream, and method for etching nano silver conductive material by utilizing etching cream”, which describes the use of an etching paste by first printing then heating the paste at 60-130° C. for around 10 minutes before washing with water to remove the etching paste and etched material. Examples of other alternative etching techniques include, but are not limited to, vapour phase etching and plasma etching. The chemical process in vapour phase etching is analogous to that used in the solution etching, wherein reactive gases are used to remove the conductive material. Typically, this technique uses a mixture of an oxidizing agent and co-ordinating ligand to first oxidize and then complex the conductive material to form a volatile product that dissipates from the surface.

The production of fabrics with patterned conductive and nonconductive areas using protective masks and etchants is something that has been included in prior art, such as US20090266788 and DE102009033510A1. However, it is often the case that when processing the protective coating pattern it is not fully considered that the fabric could be conductive on both sides, and only use substrates that are made conductive on only one side, such as ITO-coated PET, and do not cover the requirement for protecting both the front and rear sides of the conductive fabric, something that will be highly disadvantageous to the user when uniformly coated conductive fibres are used to create the fabric. By not coating all sides of the fibres accurately and at the same time the result will be fibres which have been protected from the etchant on the “front” side, the side of the fabric to which the protective coating was applied, whilst the protective coating will not be fully present on the “rear” side meaning that the conductive coating will be fully or partly removed. The result is a conductive pattern which is will be less conductive than is possible. For applications like complex conductive circuits with small line widths this will be highly disadvantageous, especially if high current applications are required.

However, there still exists a need for a process that creates a fabric which is uniformly conductive, two-sided, flexible and stretchable, feels and acts like a typical fabric, and can be patterned in such a way that it is possible to form complex patterns and small features, such as for example SMD attachment.

It is an object of the present invention to seek to mitigate problems such as those described above.

### SUMMARY OF THE INVENTION

According to a first aspect of the invention there is provided a method of forming conductive and nonconductive areas on a conductive fabric, the fabric comprising non-conductive fibres coated with conductive material prior to forming the fabric, the method comprising depositing an etch-resistant emulsion, capillary film or paste on both sides of the fabric that covers the area desired to be conductive, removing conductive material from a non-coated area using an etching agent, and removing the etch-resistant coating to reveal a conductive area.

Advantageously, the method of the present invention may provide conductive circuits for the formation of electric devices on a previously uniform conductive-particle coated fabric (from now on known as conductive coated fabric) with a high resolution between the conductive and nonconductive areas. The circuits offer greater flexibility of the fabric and greater conductivity of the circuit. By carefully choosing the conductive fabrics, etchants and etching conditions, it is possible to accurately and repeatedly etch high resolution patterns. This is achieved firstly by coating the fibres with a conductive coating prior to forming the fabric. For example, the fibres can be coated with a controlled thickness of conductive metal using an automated roll-to-roll process such as sputtering. Advantageously sputter coating results in a fibre with a homogeneous and uniform coating and which therefore has a uniform conductivity on all sides and along its whole length.

Following the coating step, the fibres are then woven into a mesh or fabric which demonstrates uniform conductivity in every direction and at every point, even between the fibre joints, taking into account construction based directional bias. Advantageously, by coating the conductive material onto the fibres before weaving into a fabric we have ensured that there a reliable connection between the fibres and therefore a stable conduction path when at rest and under flexing or stretching.

The method advantageously involves the use of conductive metals, metal alloys, metal-inorganic mixtures, or conductive inorganic materials. These material types have been selected because they are inherently more robust than organic polymers whilst at the same time being many orders of magnitude more conductive. These advantages make inorganic materials significantly better than organic polymers for the purpose of creating conductive fabric circuits by coating nonconductive fibres with a conductive coating.

The formation of a uniform and homogeneous conductive coating on the fibres prior to weaving the fabric, which covers all sides of the fibres evenly when it is done using a suitable technique such as sputtering, is very important because it advantageously allows controllable predictable and reliable etching of the conductive coating and therefore accurate and repeatable conductive pattern creation. Sputtering is already widely used to create conductive coatings on flat substrates such as indium tin oxide on polyethylene terephthalate, and is a good method for production of homogeneous coatings with a uniform and controllable thickness.

The method then involves the creation of patterned conductive and nonconductive areas on the as-formed block of conductive fabric by removing the conductive coating from the nonconductive fibres. The removal of conductive coatings can be done using a number of well-known techniques such as using directed water jets, chemical etching or other processes known to the art. However, the minimum feature size of many of these processes are not ideal for producing conductive fabrics with small or complex circuits on, and especially for producing circuits to which components, such as SMDs, are to be attached because the contact size, inter-contact spacing and contact form must be accurately reproducible and will not work unless they are ideally addressed. The method overcomes this problem using duplex printing of protective coatings, photohardenable emulsions or capillary film to form high resolution coating patterns on the fabric and in doing so allows the formation of circuit features of a size comparable with those on common PCB architectures, and in doing so allowing the use of standard electronic components. The creation of small feature size patterns has added significance when high thread count fabrics are required because they possess a greater density of threads and so more conductive paths from which complex and small feature size patterns and circuits can be formed. Duplex printing is a technique that is known to those with knowledge of the printing art and is a process that will deposit a protective coating on both sides of a fabric at once. Set up correctly this technique can be highly accurate and produce high resolution prints that are accurately lined up with each other so that both sides of a fabric are coated with the correct protective pattern and therefore well protected from the etchant, allowing complete and accurate production of the conductive and nonconductive pattern areas with a resolution and conductivity applicable to, for instance, forming complex conductive circuits. Photohardenable emulsions and capillary films are well known in the art of screen printing and are a paste or a pre-formed film which will harden to a solid coating upon exposure to actinic radiation. In this application photonegatives of the desired conductive pattern are placed over the emulsion or capillary film before exposure. The photonegative image is made from a material that is opaque to the actinic radiation. The effect is that the area under the photonegative is protected from the actinic radiation whilst all other areas are exposed. The un-exposed areas remain unhardened and are easily removed from the fabric during the subsequent washing to leave the conductive coated fabric underneath them exposed. The fabric is then exposed to the etchant, usually a liquid or paste, for long enough at a suitable temperature that the conductive coating is removed from the fibres. The emulsion or capillary film is then removed using specific chemicals to reveal the conductive patterned fabric underneath. The emulsion or capillary film is specifically chosen to be resistive to the etchant and to allow the formation of even the smallest features of the conductive pattern by strongly adhering to the coated fibres during the etching but not damaging the coated fibres when applied and specifically during application or removal. For instance, if a water-based etchant such as ferric nitrate solution is to be used, then a suitable emulsion such as CPS ultra-coat 200-water resistant emulsion can be used. Advantageously emulsions and capillary films protect both sides of the conductive fabric despite being applied from only one side.

Embodiments of the invention are applicable to conductive fabrics created by coating the surface of an otherwise nonconductive fibre, filament or yarn with a conductive metal, a metal-metal alloy, a metal-inorganic mixture, a metal-organic mixture, or conductive inorganic material such as carbon, hereafter known as conductive coated fibres.

The coating can be achieved by depositing the conductive coating using a controlled coating technique to achieve a uniform, homogeneous coating of specific thickness. This can include, but is not limited to, sputter coating, carbon coating, and vacuum and evaporation deposition techniques. The fibres which comprise the fabric may have a conductive particulate material deposited on them by techniques such as, but not limited to, sputter-coating, chemical vapour deposition, vacuum deposition techniques, and solution processing.

The term fibre, filament and yarn shall be used interchangeably herein to mean the individual constituent textile elements from which the textile fabric discussed herein are constructed.

Patterned conductivity can be achieved by depositing a material resistant to the chemical etching agents onto a conductive coated fabric. Then a chemical etching agent is applied to the fabric, removing the conductive particle coating on the exposed fibres and not where the patterned etch-resistant coating has been applied. The patterned etch-resistant coating is then removed by washing with an appropriate solvent to reveal the patterned conductive area or circuit. The removal of conductive material may also be performed through the use of an etching paste, vapour phase etching or plasma etching.

For solution etching it is preferred that the deposition of the etch-resistant coating is performed in such a way that both sides of the conductive coated fabric are coated at the same time and to the same degree, and that the coating is performed by duplex printing techniques known to the art, such as screen printing or flexographic printing. It is similarly preferred that the method comprises the step of allowing the etch-resistant coating to be adequately treated so that it is cured and is solid before the etching step. It is then preferred that the next step of the method comprises exposing the patterned conductive textile to a chemical etchant for a suitably long time and at a temperature that will remove the particulate coating of conductive material from the surface of the underlying fibres sufficiently that the etching area has become non-conductive. It is preferred that this etching step is performed by submerging the conductive coated fabric in an etchant solution.

Solution etching can however also consist of spraying or painting of the etchant solution onto the exposed fibres, or using any other technique known to the art.

For etching using etching paste the first step involves the deposition of the etching paste, preferably performed by duplex printing techniques. It is then preferred that the etching paste is allowed to work until the etching agent has eliminated the conductive material. It is also preferred that the etching paste and any etched material is removed by washing with or submersion within a suitable solvent.

Patterned conductivity can also be achieved using an etching paste instead of an etching solution. It is preferred that first the surface of the conductive material is washed and dried to remove any contaminants. It is then preferred that an etching paste is applied to the conductive fabric in a negative pattern of where the conductive material is required, it is further preferred that the etching paste is applied evenly across both sides of the fabric in the areas which are to be etched simultaneously. The deposition of the etching paste is preferably done using duplex screen printing, but can also be done using any other printing or coating technique known to the art. The conductivity of the conductive material is then degraded and preferably the conductive material is removed completely by the etching paste over a set or predetermined time at a set or predetermined temperature. The etching paste and any etched material are then removed by washing, revealing the etched nonconductive patterns. The fabric is then dried, preferably at room temperature, but drying can also be done at higher temperatures and/or with a blown stream of dry air.

Another alternative technique to achieve patterned conductivity on uniform conductive fabrics is vapour phase etching. Preferably the conductive fabric is first printed with an etch-resistant coating in a pattern which is a positive of the required conductive areas. The fabric is then placed in a vacuum chamber with a source of oxidizing agent and co-ordinating agent, the pressure of the vacuum chamber is reduced to volatize the liquids to form a vapour; this process can be helped by applying heat. The vapour is then allowed to etch the conductive material for a specific amount of time, when completed the vacuum is released and the conductive fabric is then removed from the vacuum chamber and washed with deionized water and allowed to dry at room temperature.

The conductive coated fibres of the present invention may be woven, knit, or non-woven to produce the conductive fabric. The fibres which comprise the fabric may be formed of a wide variety of natural or synthetic materials which can include, but are not limited to, polyesters, polyolefins, polyamides, ceramic, and cellulose-based fibres.

The etch-resistant coating may comprise any or a combination of a large number of polymers and co-polymers insoluble in water including, but not limited to, poly(carbonate) poly(vinylidene chloride), poly(amide), poly(imide), poly(ether) poly(vinyl chloride), poly(vinyl ester), poly(ester), poly(vinylpyridene) and poly(vinylidene chloride)-poly(acrylic acid).

The etching paste may comprise any or a combination of a large number of polymer and co-polymers soluble in water including, but not limited to, poly(acrylic acid), poly(ethylene glycol), poly(ethylene oxide), poly(methacrylic acid), poly(ethylenimine), poly(acrylamide), poly(styrene sulfonate), poly(vinylpyrrolidone) and dextran.

Chemical etching agents are used to degrade and reduce the conductivity of the conductive coated fabric. The use of such etching agents has been previously discussed in a number of patents, examples of which are U.S. Pat. No. 5,162,135 and U.S. Pat. No. 5,624,736 which describe the etching of conductive polymers from the surface of nonconductive fibres. Such documents discuss suitable reducing agents such as zinc formaldehyde sulfoxylate, sodium formaldehyde sulfoxylate, thiourea dioxide, sodium hydrosulphite, sodium borohydride, hydrazine and ammonium hydroxide formed into a suitable aqueous solution and suitable oxidization agents such as sodium hypochlorite and hydrogen peroxide. The etching effect of reasonable concentrations of such chemicals would be less for silver-based conductive coatings.

It is preferred that the chemical etchant is an aqueous solution containing one or more components which may or may not include inorganic salts, acidic etchants, basic etchants, oxidizing agents, reducing agents and co-ordinating ligands. The inorganic salts may include, but are not limited to, aluminium chloride, iron nitrate, iron chloride, iron cyanide, potassium nitrate, potassium thiosulfate, sodium nitrate, sodium chloride and sodium chlorate. The acidic etchants may include, but are not limited to, oxalic acid, nitric acid, acetic acid, formic acid, phosphoric acid, hydrochloric acid, hydrofluoric acid and sulphuric acid. The basic etchants may include, but are not limited to, ammonia, ammonium hydroxide, calcium carbonate, potassium carbonate, lithium hydroxide, sodium hydroxide. The oxidizing agents may include, but are not limited to, hydrogen peroxide, osmium tetroxide, peracetic acid, sodium dichromate, chromic acid, ammonium dichromate, potassium dichromate, nitric acid, potassium permanganate, ammonium persulfate, nitrous oxides, nitrosyl halides, cyanide, isocyanide, barium periodate, sodium perchlorate, potassium perchlorate, sodium hypochlorite, and tetrafluoromethane. The reducing agents may include, but are not limited to, sodium borohydride, lithium aluminium hydride, triethylborane, lithium hydride and triethylsilane. The co-ordinating ligands may include, but are not limited to, thiosulfate, cyanide, fluorine, iodine, bromine, chlorine, thiocynanide, thiourea, hexafluoroacetylacetone, and hydroxyl ions.

### DETAILED DESCRIPTION OF EMBODIMENTS OF THE INVENTION

Specific embodiments of the invention will further be described by way of example only.

Embodiments of the present invention relate to a simple method of producing electrically conductive patterns on a textile fabric by removing conductive material from the surface of an area of conductively-coated fibres by printing a pattern of etch-resistant coating on the surface of the conductive fabric and subsequently etching away the conductive material from the exposed parts of the fabric to leave a pattern of nonconductive areas.

### EXAMPLE 1

An exemplary method of forming a nonconductive pattern on a uniformly silver-coated nanoparticulate fibre fabric involves first the printing of an etch-resistant polymer mask of WPS Black Paper and Board ink, produced and supplied by Wicked Printing Stuff, onto the conductive fabric, preferably so that both sides of the fabric are coated at the same time using a duplex screen printing machine. The ink is printed in a pattern that is a positive of where the conductive areas should be on the finished material and is allowed to dry at 130° C. for 10 minutes. Next an etching solution is prepared by adding 0.1 moles of iron (III) nitrate to a litre of deionised water with stirring until all solids have dissolved. The conductive fabric is then immersed uniformly in the etching solution for 5 minutes at room temperature. The fabric is then removed from the etching solution and washed with deionised water to remove any remaining etching solution before it is allowed to dry completely. The etch-resistant polymer mask is then removed using an organic solvent wash such as WPS High Strength Screen Wash and the fabric is then left to dry at room temperature.

### EXAMPLE 2

Another method of forming a non-conductive pattern on a uniformly coated silver-particle coated fibre fabric may involve first the printing of an etching paste containing an acidic etching agent, inorganic metal salt, acidic oxidant, water soluble polymer and solvent onto the conductive fabric. The etching paste is printed in a pattern that is a negative of where the conductive areas should be on the finished material and is allowed to dry at room temperature for 10 minutes. Next the printed fabric is heated for 10 minutes at 60-130° C., then the etching paste is washed off using deionised water and the patterned conductive fabric is left to dry at room temperature.

### EXAMPLE 3

Yet another method of forming a nonconductive pattern on a uniformly coated conductive silver-particle coated fibre fabric may involve first applying Ulano DP9250 water resistant emulsion to the fabric and then drying the emulsion. A photopositive of the conductive pattern is then applied to the fabric and they are exposed to actinic radiation for a sufficient amount of time that the exposed areas of the emulsion have hardened. The unhardened areas are then washed out using water before the fabric is placed into an etching solution. Next an etching solution is prepared by adding 0.1 moles of iron (III) nitrate to a litre of deionised water with stirring until all solids have dissolved. The conductive fabric is then immersed uniformly in the etching solution for 5 minutes at room temperature. The fabric is then removed from the etching solution and washed with deionised water to remove any remaining etching solution before it is allowed to dry completely. The hardened emulsion mask is then removed using stencil strip solution and the fabric is then left to dry at room temperature.

### Alternative Embodiments

Alternative embodiments which may be apparent to the skilled person on reading the above description may nevertheless fall within the scope of the invention, as defined by the accompanying claims.

1. A method of forming conductive and nonconductive areas on a conductive fabric, the fabric comprising non-conductive fibres coated with conductive material prior to forming the fabric, the method comprising:
depositing at least one of an etch-resistant emulsion, capillary film and paste on both sides of the fabric that covers an area of the fabric desired to be conductive,
removing conductive material from a non-coated area of the fabric using an etching agent, and
removing at least one of the etch-resistant emulsion, capillary film and paste to reveal a conductive area.

2. The method of claim 1, wherein the conductive material comprises at least one of a conductive metal, a metal-metal alloy, a metal-inorganic mixture, a conductive inorganic material.

3. The method of claim 1, wherein removal of the conductive material from the non-coated area using the etching agent comprises chemical solution etching.

4. The method of claim 3, wherein the chemical solution etching comprises submerging the conductive coated fabric in at least one of an etchant solution, spray etching, and painting etching.

5. The method of claim 1, wherein removal of the conductive material is performed through use of at least one of an etching paste, vapor phase etching, and plasma etching.

6. The method of claim 5, wherein the etching paste comprises at least one of poly(acrylic acid), poly(ethylene glycol), poly(ethylene oxide), poly(methacrylic acid), poly(ethylenimine), poly(acrylamide), poly(styrene sulfonate), poly(vinylpyrrolidone), and dextran.

7. The method of claim 1, wherein the etching agent comprises at least one of zinc formaldehyde sulfoxylate, sodium formaldehyde sulfoxylate, thiourea dioxide, sodium hydrosulphite, sodium borohydride, hydrazine, ammonium hydroxide, and oxidization agents.

8. The method of claim 1, wherein the etching agent comprises at least one of an inorganic salt, an acidic etchant, a basic etchant, an oxidizing agent, a reducing agent, and a coordinating ligand.

9. The method of claim 8, wherein the inorganic salt comprises at least one of aluminium chloride, iron nitrate, iron chloride, iron cyanide, potassium nitrate, potassium thiosulfate, sodium nitrate, sodium chloride, and sodium chlorate.

10. The method of claim 8, wherein the acidic etchant comprises at least one of oxalic acid, nitric acid, acetic acid, formic acid, phosphoric acid, hydrochloric acid, hydrofluoric acid, and sulphuric acid.

11. The method of claim 8, wherein the basic etchant comprises at least one of ammonia, ammonium hydroxide, calcium carbonate, potassium carbonate, lithium hydroxide, and sodium hydroxide.

12. The method of claim 8, wherein the oxidizing agent comprises at least one of hydrogen peroxide, osmium tetroxide, peracetic acid, sodium dichromate, chromic acid, ammonium dichromate, potassium dichromate, nitric acid, potassium permanganate, ammonium persulfate, nitrous oxides, nitrosyl halides, cyanide, isocyanide, barium periodate, sodium perchlorate, potassium perchlorate, sodium hypochlorite, and tetrafluoromethane.

13. The method of claim 8, wherein the reducing agent comprises at least one of sodium borohydride, lithium aluminium hydride, triethylborane, lithium hydride, and triethylsilane.

14. The method of claim 8, wherein the coordinating ligand comprises at least one of thiosulfate, cyanide, fluorine, iodine, bromine, chlorine, thiocynanide, thiourea, hexafluoroacetylacetone, and hydroxyl ions.

15. The method of claim 5, wherein the etching paste is applied to the conductive fabric by at least one of screen-printing and flexographic printing.

16. The method of claim 15, wherein removal of the conductive material is performed on both sides of the fabric simultaneously.

17. The method of claim 1, wherein depositing at least one of the etch-resistant emulsion, capillary film and paste is performed through the use of at least one of an emulsion, capillary film, simultaneous duplex printing process, screen printing, and flexographic printing.

18. The method of claim 1, comprising curing at least one of the etch-resistant emulsion, capillary film and paste prior to removing the conductive material from the non-coated area of the fabric.

19. The method of claim 1, wherein at least one of the etch-resistant emulsion, capillary film and paste comprises at least one of poly(carbonate) poly(vinylidene chloride), poly(amide), poly(imide), poly(ether) poly(vinyl chloride), poly(vinyl ester), poly(ester), poly(vinylpyridene), and poly(vinylidene chloride)-poly(acrylic acid).

20. The method of claim 1, wherein at least one of the fabric and fibres are coated in the conductive material by at least one of sputter coating, carbon coating, chemical vapour deposition, vacuum deposition techniques, evaporation deposition techniques, and solution processing.

21. The method of claim 1, wherein the conductive material is silver based.

22. The method of claim 1, wherein the fibres comprise at least one of polyester, polyolefins, polyamides, ceramics, and cellulose based fibres.

23. The method of claim 1, wherein the fabric is at least one of an article of clothing and a wearable fabric.

24. A patterned textile fabric with conductive and nonconductive areas, produced by the method of claim 1.

25. The method of claim 2, wherein the conductive inorganic material comprises carbon.

26. The method of claim 7, wherein the oxidization agents comprise at least one of sodium hypochlorite and hydrogen peroxide.
